(19) United States
(12) Patent Application Publication
(10) Pub. No.: US 2020/0028050 A1
(43) Pub. Date: Jan. 23, 2020

(54) THERMOELECTRIC CONVERSION MATERIAL, THERMOELECTRIC CONVERSION MODULE, AND PRODUCTION METHOD OF THERMOELECTRIC CONVERSION MATERIAL

(71) Applicant: HITACHI METALS, LTD., Tokyo (JP)

(72) Inventors: Akinori NISHIDE, Tokyo (JP); Naoto FUKATANI, Tokyo (JP); Jyun HAYAKAWA, Tokyo (JP)

(73) Assignee: HITACHI METALS, LTD., Tokyo (JP)

(21) Appl. No.: 16/234,061

(22) Filed: Dec. 27, 2018

(30) Foreign Application Priority Data
Dec. 28, 2017 (JP) 2017-253442

(51) Int. Cl. H01L 35/22; H01L 35/08; H01L 35/34; H01L 35/32; C22C 45/02; C22C 33/02

(52) U.S. Cl. CPC H01L 35/22; H01L 35/08; C22C 33/0207; H01L 35/32; C22C 45/02; H01L 35/34

(57) ABSTRACT

According to one embodiment, a thermoelectric conversion material includes a main phase and a grain boundary phase, the main phase is a Fe₂TiSi-based full Heusler alloy, the grain boundary phase includes a metal N slightly solid-soluble in Fe₂TiSi, and a volume ratio of the grain boundary phase is 2% to 10%.

### BACKGROUND OF THE INVENTION

### 1. Field of the Invention

The present invention relates to a thermoelectric conversion material, a thermoelectric conversion module using the same, and a production method thereof.

### 2. Description of Related Art

PTL 1 (WO 2016/185852) discloses a thermoelectric conversion material which is formed of a full Heusler alloy using Fe, Ti, and Si, and includes Sn, Cu, V, etc.

As described in PTL 1, thermoelectric conversion efficiency of a thermoelectric conversion module depends on a dimensionless performance index ZT. Herein, ZT is a dimensionless performance index obtained by multiplying a performance index Z by an absolute temperature T, and Z=S²/(κρ) (S is a Seebeck coefficient, ρ is an electrical resistivity, and κ is a thermal conductivity) is satisfied. Accordingly, there is a need to increase the Seebeck coefficient S of the thermoelectric conversion material, to reduce the electrical resistivity ρ thereof, and to reduce the thermal conductivity κ thereof in order to increase an output of the thermoelectric conversion module.

However, the related-art thermoelectric conversion material has a problem that, even if a composite material is formed with a low-resistance alloy to reduce the electrical resistivity ρ, the thermal conductivity η increases, and as a result, a high ZT cannot be obtained.

### SUMMARY OF THE INVENTION

Therefore, an object of the present invention is to increase a performance index by reducing the thermal conductivity κ of a thermoelectric conversion material, while reducing the electrical resistivity ρ of the thermoelectric conversion material.

An aspect of the present invention provides a thermoelectric conversion material, including a main phase and a grain boundary phase, in which the main phase is a Fe₂TiSi-based full Heusler alloy, the grain boundary phase includes a metal N slightly solid-soluble in Fe₂TiSi, and a volume ratio of the grain boundary phase is 2% to 10%.

Another aspect of the present invention provides a thermoelectric conversion module, including a thermoelectric conversion unit, and a first electrode and a second electrode which electrically and thermally contact the thermoelectric conversion unit, in which at least apart of the thermoelectric conversion unit is formed of a thermoelectric conversion material, the thermoelectric conversion material includes a main phase and a grain boundary phase, the main phase is a Fe₂TiSi-based full Heusler alloy, the grain boundary phase includes a metal N slightly solid-soluble in Fe₂TiSi, and a volume ratio of the grain boundary phase is 2% to 10%.

Still another aspect of the present invention provides a production method of a thermoelectric conversion material, the method including: a preparation process of preparing raw material powder of an amorphized Fe₂TiSi-based full Heusler alloy, and raw material powder including a metal N; a heating process of heating the raw material powder; and a cooling process of cooling a product material after the heating process, in which a grain boundary phase is formed between main phases of a thermoelectric conversion material formed of the Fe₂TiSi-based full Heusler alloy, by precipitating the metal N, and a volume ratio of the grain boundary phase is 2% to 10%.

According to the present invention, a performance index can be enhanced by reducing the thermal conductivity κ of the thermoelectric conversion material, while reducing the electrical resistivity ρ.

### BRIEF DESCRIPTION OF THE DRAWINGS

FIG. 1 is a schematic diagram of tissue of a thermoelectric conversion material of an embodiment;

FIG. 2 is a graph diagram illustrating a relationship among an average crystal grain size (horizontal axis), a performance index ZT (vertical axis), and a thermal conductivity κ depending on the crystal grain size of the thermoelectric conversion material of the embodiment and a related-art Fe₂VAl-based full Heusler alloy;

FIG. 3 is a perspective view of a thermoelectric conversion module of the embodiment;

FIG. 4 is another perspective view of the thermoelectric conversion module of the embodiment;

FIG. 5 is a view illustrating a TEM image of material tissue of a Fe₂TiVSi-based thermoelectric conversion material of the embodiment;

FIGS. 6A to 6G are column mapping diagrams of the Fe₂TiVSi-based thermoelectric conversion material of the embodiment, obtained by STEM-EDX;

FIGS. 7A and 7B are views of comparison of a STEM image and STEM-EDX mapping of the Fe₂TiVSi-based thermoelectric conversion material of the embodiment;

FIG. 8A is a graph diagram comparing characteristics of a crystal grain size and a Seebeck coefficient of the thermoelectric conversion material of the embodiment and a comparative example;

FIG. 8B is a graph diagram comparing characteristics of the crystal grain size and an electrical resistivity of the thermoelectric conversion material of the embodiment and the comparative example;

FIG. 8C is a graph diagram illustrating a relationship between a Cu volume ratio and a thermal conductivity of the thermoelectric conversion material of the embodiment;

FIG. 8D is a graph diagram illustrating a relationship between the Cu volume ratio and a performance index of the thermoelectric conversion material of the embodiment; and

FIG. 9 is a graph diagram illustrating an effect of a thermal conductivity achieved by adding La to Cu of the thermoelectric conversion material of the embodiment.

### DESCRIPTION OF EMBODIMENTS

An embodiment described below is divided into a plurality of sections or embodiments when necessary for the sake of convenience, but unless otherwise specified, the embodiments are not unrelated to each other, and one is related to modification examples, details, supplementary explanations, etc. of a part or entirety of the other one.

In the embodiments described below, when a number, etc. of an element (including the number, a numerical value, a quantity, a range, etc.) is mentioned, unless otherwise specified and unless the element is principally and clearly limited to a specific number, the element is not limited to the specific number, and may be greater than or equal to or less than or equal to the specific number.

Furthermore, in the embodiments described below, components thereof (including element steps, etc.) are not necessarily essential components unless otherwise specified and unless it is considered that they are principally and clearly essential components. Similarly, in the embodiments described below, when shapes, positional relationship, etc. of components, etc. are mentioned, shapes, etc. substantially approximating or being similar to the shapes, etc. are included unless otherwise specified and unless it is considered that this is principally and clearly not the case. This is equally applied to the numerical value and the range described above.

Hereinafter, embodiments of the present invention will be described in detail with reference to the drawings. In the all drawings for explaining the embodiments, the same signs are used for the elements having the same functions, and a redundant explanation thereof is omitted. In addition, in the embodiments described below, explanations of the same or similar parts are not repeated in principle unless necessary.

In the embodiments described below, when a range is indicated by A to B, the range is from A to B inclusive unless otherwise specified.

1. Constitution of a Thermoelectric Conversion Material

The inventors employed, as a thermoelectric conversion material of the present embodiment, a thermoelectric conversion material which includes a main phase and a grain boundary phase, in which the main phase is a Fe₂TiSi-based full Heusler alloy, the grain boundary phase is formed of a metal alloy N slightly solid-soluble in the Fe₂TiSi-based full Heusler alloy, and a volume ratio of the grain boundary phase is 2% to 10%. Herein, the main phase refers to a phase having a highest phase ratio, and generally refers to a key material which has the greatest effect on characteristics of a corresponding material. Although the metal alloy N is referred to as a “metal alloy N” in the present specification for the sake of convenience, the metal alloy N may be referred to as a metal N, and may be a monometal. In addition, a semimetal, etc. may be added. Herein, the metal alloy N is specifically an alloy formed of an element slightly solid-soluble in the Fe₂TiSi-based full Heusler alloy, such as Cu.

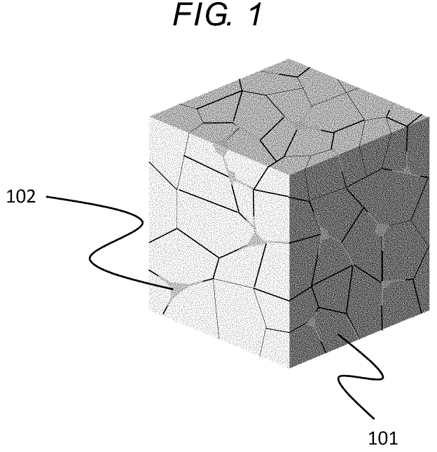

FIG. 1 is a schematic diagram of tissue of the corresponding material. A grain boundary phase 102 of the metal alloy N exists between main phases 101 of the Fe₂TiSi-based full Heusler alloy. In forming the composite structure as described above, it is desirable that the main phase 101 having a high Seebeck coefficient S is selected, and the grain boundary phase 102 having a low electrical resistivity ρ is selected. By doing so, the Seebeck coefficient S can be maintained at a high level from the physical property of the main phase, and the electrical resistivity ρ can be reduced by the physical property of the metal alloy N of the grain boundary phase. Furthermore, the thermal conductivity κ can be maintained at a low level since scattering of phonons is promoted in a condition (condition 1) where a grain size is a nanoscale size, and a condition (condition 2) where the grain boundary phase is a nanoscale size.

As a constitution for realizing the above-described characteristics and principle, a full Heusler alloy expressed by the compositional formula Fe₂TiSi, that is, the Fe₂TiSi-based full Heusler alloy is employed for the main phase 101. That is, the thermoelectric conversion material of the present embodiment is formed of the full Heusler alloy which contains iron (Fe), titanium (Ti), and silicon (Si) as main components.

In the present specification, the full Heusler alloy containing iron, titanium, and silicon as main components means that a content of iron exceeds 25 at % (atom %), a content of titanium exceeds 12.5 at % (atom %), and a content of silicon exceeds 12.5 at % (atom %).

That is, this means that in the full Heusler alloy having an L2₁ type crystal structure expressed by E1₂E2E3, more than 50% of E1 sites among the all E1 sites are occupied by the iron atom. In addition, this means that more than 50% of E2 sites among the all E2 sites are occupied by the titanium atom, and more than 50% of E3 sites among the all E3 sites are occupied by the silicon atom.

In addition, the grain boundary phase contains the metal alloy N slightly solid-soluble in Fe₂TiSi. The metal alloy N needs to be formed by being precipitated from Fe₂TiSi as a desirable metallurgical property as will be described below. Therefore, there is a need to select an element which is slightly solid-soluble in Fe₂TiSi. In addition, a metal alloy having a low electrical resistivity is desirable, and in particular, a metal alloy in which electrical conduction by an s electron is dominant is suitable. Accordingly, as the metal alloy N, an alloy including at least one element selected from Cu, Ag, Au, La, Bi, and Nb as a main component is desirable. Herein, the main component indicates that 50% or more of the alloy is formed of at least one kind of material selected from Cu, Ag, Au, La, Bi, and Nb. Herein, a component ratio is a weight ratio of component elements in the alloy.

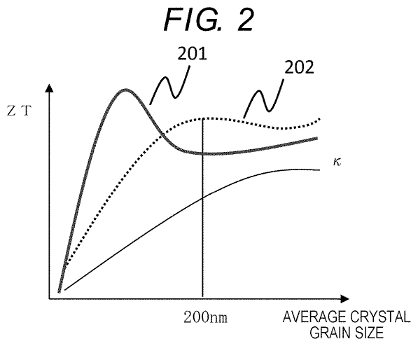

FIG. 2 schematically illustrates comparison of a relationship among an average crystal grain size (horizontal axis), a performance index ZT (vertical axis), and a thermal conductivity κ depending on the crystal grain size of the thermoelectric conversion material of the present embodiment having a structure illustrated in FIG. 1, and a related-art Fe₂VAl-based full Heusler alloy.

As illustrated in FIG. 2 of PTL 1, in a characteristic 202 of the related-art Fe₂VAl-based full Heusler alloy, if the thermal conductivity κ is reduced by reducing the average grain size of the crystal grain, the electrical resistivity ρ increases, the output factor S²/ρ in Z=S²/(κρ) is reduced, and as a result, ZT is reduced.

On the other hand, in the thermoelectric conversion material of the present embodiment, which includes the Fe₂TiSi-based full Heusler alloy as the main phase and includes the metal alloy N as the grain boundary phase, as illustrated by a characteristic 201 of FIG. 2, unlike the characteristic 202 of the Fe₂VAl-based full Heusler alloy, even if the thermal conductivity κ is reduced by reducing the average grain size of the crystal grain to about 200 nm or less, the output factor S²/ρ is maintained or greatly increases, and thus ZT increases.

In addition, the Fe₂TiSi-based full Heusler alloy has the above-described high output factor S²/ρ in any case of the case where the Fe₂TiSi-based full Heusler alloy is applied to a p-type thermoelectric conversion material, and the case where the Fe₂TiSi-based full Heusler alloy is applied to an n-type thermoelectric conversion material.

In a more preferred embodiment, as the principle described in (condition 1) and (condition 2), it is desirable to micronize the main phase and the grain boundary phase to some extents to keep the thermal conductivity κ at a low level. Accordingly, according to (condition 1), it is desirable that the average grain size of the crystal grain of the Fe₂TiSi-based full Heusler alloy is less than 1 μm. Therefore, the performance index ZT can be increased in comparison to a case where the average grain size of the crystal grain exceeds 1 μm. It is more preferable that the average grain size of the crystal grain is 30 to 200 nm to further increase the performance index ZT. In addition, it is still more preferable that the average grain size of the crystal grain is 30 to 140 nm to further increase the performance index ZT. In addition, ideally, it is preferable that the average grain size is 30 to 100 nm.

For the same reason, according to (condition 2), it is desirable that the metal alloy N exists on a grain boundary in the form of a layer. If the metal alloy N is slightly solid-soluble and the volume ratio is 2% to 10%, the thickness of the metal alloy N is 1 to 10 nm with respect to the main phase having a grain size of about 50 nm as illustrated in the embodiment. That is, there is the layer of the metal alloy N having the thickness ranging from 1 to 10 nm, such that both the thermal conductivity κ and the electrical resistivity ρ can be reduced. The thickness of the layer may be defined as a shortest distance between facing crystal grains and a boundary of a metal alloy in a two-particle grain boundary phase. For example, the thickness of the layer may be measured by a transmission type electron microscope (TEM) image. It is desirable that the average thickness of the metal alloy N is included in a range of 1 to 10 nm to enhance the entire characteristics of the thermoelectric conversion material.

The metal alloy N inevitably has high electron heat conductivity due to the low electrical resistivity ρ. Therefore, the thermal conductivity κ of the metal alloy N itself is high. Accordingly, when a containing volume ratio of the metal alloy N exceeds 10%, a physical property value of the metal alloy N becomes dominant, and accordingly, the thermal conductivity increases. As a result, there is a risk that the performance index ZT is greatly reduced. Therefore, it is preferable that the containing volume ratio of the metal alloy N is 10% or less. On the other hand, if the containing volume ratio of the metal alloy N is less than 2%, the effect of reducing both the thermal conductivity κ and the electrical resistivity ρ can not be expected due to factors such as the arrangement or thickness of the grain boundary phase, and thus it is preferable that the containing volume ratio of the metal alloy N is 2% or more.

2. Production of the Thermoelectric Conversion Material

Regarding the embodiment described above, a desirable method for obtaining the same will be described. For example, a thermoelectric conversion material formed of a minute crystal grain having an average grain size of less than 1 μm can be produced by heating raw material powder of an amorphized Fe₂TiSi-based full Heusler alloy and the metal alloy N. In addition, as a production method of the raw material powder of the amorphized Fe₂TiSi-based full Heusler alloy and the metal alloy N, mechanical alloying, a method of extremely rapidly cooling after dissolving raw materials, etc. may be used.

In the process of heating the raw material powder of the amorphized Fe₂TiSi-based full Heusler alloy and the metal alloy N, as a temperature for heating is higher or the time required to heat is longer, the average grain size of the crystal grain of the thermoelectric conversion material produced is larger. By appropriately setting the temperature and the time for heating, the average grain size of the crystal grain can be controlled. For example, it is preferable that the temperature for heating is 550° C. to 700° C., and the time required to heat is from 3 minutes to 10 hours inclusive.

In addition, to make the average grain size of the crystal grain be included in the range of 30 to 140 m, it is desirable that the raw material powder of the amorphized Fe₂TiSi-based full Heusler alloy and the metal alloy N is put into a die formed of carbon or a die formed of tungsten carbide, and is sintered by applying a pulse current under pressure of 40 MPa to 5 GPa in an inert gas atmosphere. It is preferable that when the powder is sintered, the temperature increases to a target temperature of a range of 550° C. to 700° C., the powder is maintained at the target temperature for 3 to 180 minutes, and then the temperature decreases to a room temperature.

When raw material powder of the Fe₂TiSi-based full Heusler alloy and the metal alloy N is heated by the above-described method, the metal alloy N is not solid-soluble in the crystal of the Fe₂TiSi-based full Heusler alloy of the main phase. Accordingly, when the raw material powder of the amorphized Fe₂TiSi-based full Heusler alloy and the metal alloy N is heated, the metal alloy N is precipitated separately from the main phase, and is crystallized as the grain boundary phase. In this case, since the metal alloy N suppresses a crystal growth of the Fe₂TiSi-based full Heusler alloy of the main phase, the crystal grain of the Fe₂TiSi-based full Heusler alloy can be micronized. Accordingly, the metal alloy N is also referred to as a crystal grain size control alloy.

In addition, if an element such as carbon (C), oxygen (O), or nitrogen (N) is solid-soluted in the full Heusler alloy as the main phase, an alloy or a compound is formed at a temperature which is lower than a precipitation temperature of the main phase. Accordingly, by solid-soluting an element such as carbon, oxygen, or nitrogen in the main phase, the crystal grain can be micronized in the same way as the above-described crystal grain size control alloy. It is preferable that a content (an amount of addition) of the element such as carbon, oxygen, or nitrogen is 1000 ppm or less.

In addition, as a method for amorphizing the raw materials of the Fe₂TiSi-based full Heusler alloy and the metal alloy N, methods such as roller rapid cooling and atomization may be used. When the amorphized material is not obtained as powder, a method of grinding in an environment in which hydrogen embrittlement and oxidization are prevented may be used.

As a method for molding the raw materials, various kinds of methods such as pressure molding may be used. Sintering may be performed in a magnetic field, and a sintered body oriented in the magnetic field may be obtained. In addition, discharge plasma sintering capable of performing pressure molding and sintering simultaneously may be used.

3. Thermoelectric Conversion Module

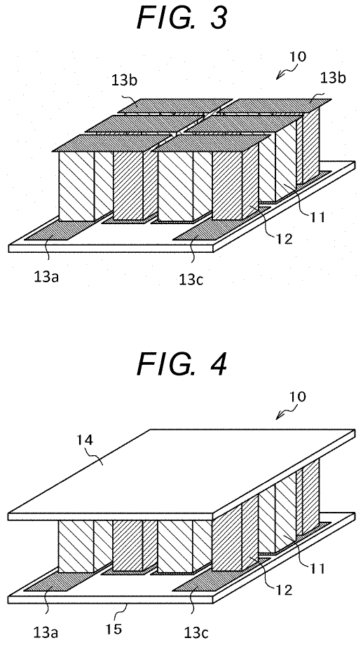

A thermoelectric conversion module using the thermoelectric conversion material of the present embodiment will be described with reference to FIGS. 3 and 4. FIG. 3 illustrates a state before an upper substrate is installed, and FIG. 4 illustrates a state after the upper substrate is installed.

The thermoelectric conversion material of the present embodiment may be mounted in a thermoelectric conversion module illustrated in FIGS. 3 and 4, for example. The thermoelectric conversion module 10 includes a p-type thermoelectric conversion unit 11, an n-type thermoelectric conversion unit 12, a plurality of electrodes 13, an upper substrate 14, and a lower substrate 15. In addition, the thermoelectric conversion module 10 includes an electrode 13a, an electrode 13b, and an electrode 13c as the plurality of electrodes 13.

The p-type thermoelectric conversion unit 11 and the n-type thermoelectric conversion unit 12 are connected with each other in series between the electrode 13a and the electrode 13c. An electrode other than the electrode 13a and the electrode 13c is the electrode 13b, and the p-type thermoelectric conversion unit 11 and the n-type thermoelectric conversion unit 12 are connected with each other in series via the electrode 13b. The electrodes 13a and 13c are formed on the lower substrate 15. The p-type thermoelectric conversion unit 11 on the side of the electrode 13a thermally contacts the lower substrate 15, and the p-type thermoelectric conversion unit 11 on the side of the electrode 13b thermally contacts the upper substrate 14. The n-type thermoelectric conversion unit 12 on the side of the electrode 13b thermally contacts the upper substrate 14, and the n-type thermoelectric conversion unit 12 on the side of the electrode 13c thermally contacts the lower substrate 15. Accordingly, since a thermoelectromotive force generated between both ends of the p-type thermoelectric conversion unit 11, and a thermoelectromotive force generated between both ends of the n-type thermoelectric conversion unit 12 are added between the electrode 13a and the electrode 13c without being eliminated, a great thermoelectromotive force can be generated by the thermoelectric conversion module 10.

Each of the p-type thermoelectric conversion unit 11 and the n-type thermoelectric conversion unit 12 includes a thermoelectric conversion material. As the thermoelectric conversion material included in each of the p-type thermoelectric conversion unit 11 and the n-type thermoelectric conversion unit 12, the thermoelectric conversion material of the present embodiment may be used. However, a thermoelectric conversion material formed of a full Heusler alloy having tissue different from the Fe₂TiSi-based full Heusler alloy, such as Fe₂NbAl or FeS₂, may be used as the p-type thermoelectric conversion unit 11.

On the other hand, as a material of each of the upper substrate 14 and the lower substrate 15, gallium nitride (GaN), silicon nitride (Si—N), aluminum oxide, etc. may be used. In addition, as a material of the electrode 13, copper (Cu), gold (Au), etc. may be used. It is more desirable that a combination of members for mitigating a stress is selected.

Hereinafter, the present embodiment will be described in more detail. The present invention is not limited by the embodiments described below.

### First Embodiment

A thermoelectric conversion material according to the present embodiment is formed of a p-type or n-type full Heusler alloy represented by a constitution described below. Specifically, the thermoelectric conversion material includes a main phase formed of a full Heusler alloy, and a grain boundary phase formed of a metal or a semimetal. The full Heusler alloy is a Fe₂TiSi-based full Heusler alloy, and a grain size thereof is about from 30 nm to 100 nm. It is preferable that a structure of the grain boundary phase existing on a grain boundary of a crystal grain of the main phase includes a layer-shape structure adjacent to the main phase, and thickness thereof is 1 to 10 nm, and a volume ratio is 2% to 10%.

The above-described Fe₂TiSi-based full Heusler alloy refers to an alloy that includes Fe, Ti, and Si as main components, has an atomic weight ratio adjusted near to Fe:Ti:Si=50 (at %):25 (at %):25 (at %) , and has a crystal structure of the full Heusler alloy. For example, an alloy having a non-stoichiometric ratio of Fe, Ti, and Si which satisfies Fe:Ti:Si=48 (at %):25 (at %):27 (at %) is also defined in the range of the Fe₂TiSi-based full Heusler alloy. An alloy of which an element is substituted to maximize an absolute value of a Seebeck coefficient is referred to as the Fe₂TiSi-based full Heusler alloy in the same way. For example, in the n-type Fe₂TiSi-based full Heusler alloy, Ti may be appropriately substituted with V, etc. to maximize the absolute value of the Seebeck coefficient as suggested in PTL 1. Even in this case, the alloy is referred to as the Fe₂TiSi-based full Heusler alloy.

The above-described grain boundary phase is formed of the metal alloy N including an element slightly solid-soluble in the Fe₂TiSi-based full Heusler alloy. An example thereof is a Cu-based alloy. Although it is known that Fe and Cu are not solid-soluble from the well-known state diagram, the same property is identified between the Fe₂TiSi-based full Heusler alloy and the Cu-based alloy, and the above-described grain boundary may be formed. In another example, a heavy element such as La, Bi, Nb, etc. and the alloy of Cu can be applied, and a low thermal conductivity can be achieved. The same property as that of the above-described Cu-based alloy is also identified from Ag and Au, and a preferable effect can also be achieved from an Ag—La alloy, an Au—La alloy, etc.

The thermoelectric conversion material according to the present embodiment is produced by a method described below. First, regarding the Fe₂TiSi-based full Heusler alloy of the main phase, Fe₂TiVSi which includes Fe, Ti, and Si as main components, but has Ti partially substituted with V is employed. Specifically, in the thermoelectric conversion material formed of the full Heusler alloy having an L2₁-type crystal structure expressed by E1₂E2E3, iron (Fe), titanium (Ti), and silicon (Si) are used as raw materials which are main components of each site of the E1 site, the E2 site, and the E3 site. In addition, vanadium (V) is used as a raw material for substituting the main components in each site of the E2 site or E3 site. In addition, the metal alloy N of the grain boundary phase employs two kinds of alloys of Cu and Cu—La. Each raw material is weighed to make the produced thermoelectric conversion material be a desirable composition. In this case, it is preferable that the amount of the substituted element V does not exceed the amount of Ti included as a main component, and Ti is included more than V. It may be considered that Si is substituted with Al as another substitution of the element of the main component. In this case, in the same way, it is preferable that Si is included more than Al. The above-described constitution is preferable since it is possible to maintain the relationship in which the metal N is slightly solid-soluble with respect to the element which is the main component.

Next, the raw material is put into a vessel which is formed of stainless steel in an inert gas atmosphere, and is mixed with a ball formed of stainless steel and having a diameter of 10 mm. Next, mechanical alloying is performed by using a planet ball mill at a revolution speed of 200 to 500 rpm for 20 hours or longer, and amorphized alloy powder is obtained. The amorphized alloy powder is put into a die formed with carbon or a die formed with tungsten carbide, and is sintered in an inert gas atmosphere under pressure of 40 MPa to 5 GPa by applying a pulse current. When the powder is sintered, a temperature increases to a target temperature of a range of 550° C. to 700° C., then the powder is maintained at the target temperature for 3 to 180 minutes, and thereafter, the temperature is cooled to a room temperature, such that the thermoelectric conversion material is obtained.

An average grain size of a crystal grain of the obtained Fe₂TiVSi-based thermoelectric conversion material is evaluated by a transmission type electron microscope (TEM) and an X-ray diffraction (XRD) method. A thermal diffusivity of the obtained thermoelectric conversion material is measured by a laser flash method, a specific heat of the obtained thermoelectric conversion material is measured by differential scanning calorimetry (DSC), and a thermal conductivity κ is obtained from the measured thermal diffusivity and the specific heat. In addition, the electrical resistivity ρ and the Seebeck coefficient S are measured by using a thermoelectric property evaluation device ZEM (manufactured by ADVANCE RIKO, Inc.).

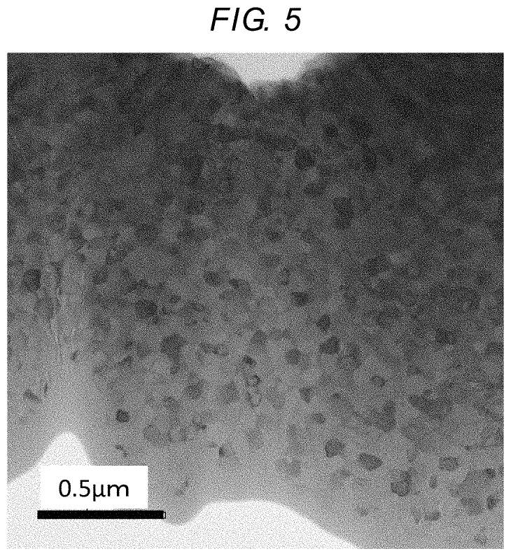

FIG. 5 illustrates a TEM image of material tissue of the obtained Fe₂TiVSi-based thermoelectric conversion material. It can be seen from the TEM image that a minute crystal grain of about 50 nm is included. Furthermore, it is recognized that the Fe₂TiSi-based full Heusler alloy has a desirable crystal structure by column mapping of a scanning transmission electron microscope-energy dispersive X-ray analysis (STEM-EDX).

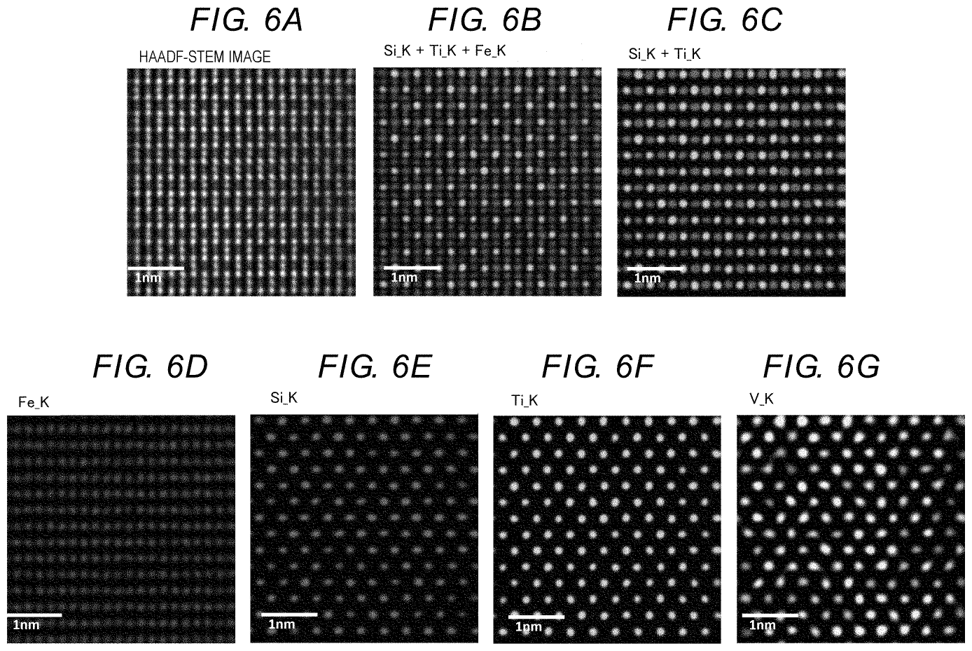

FIGS. 6A to 6G illustrate results of column mapping of the Fe₂TiVSi-based thermoelectric conversion material of the present embodiment by the STEM-EDX. FIGS. 6A to 6G illustrates a lattice image observed from a direction of (110). FIG. 6A is a STEM image, and herein, indicates a high-angle annular dark field scanning transmission electron microscope image (HAADF-STEM image). FIG. 6B illustrates arrangements of Si, Ti, and Fe. FIG. 6C illustrates arrangement of Si and Ti. FIG. 6D illustrates an arrangement of Fe. FIG. 6E illustrates an arrangement of Si. FIG. 6F illustrates an arrangement of Ti. FIG. 6G illustrates an arrangement of V.

It can be seen from FIGS. 6A to 6G that Fe, Ti, Si, and V are arranged on positions as defined by the L2₁ structure. More specifically, it can be seen that the STEM image includes an atomic row A formed of the Fe atom, and an atomic row B having Ti and Si alternately arranged, and furthermore, the atomic row A and the atomic row B are alternately arranged. In addition, it can be seen that V is also arranged on the position of Ti. From this, it can be seen that V substitution for enhancing the above-described Seebeck coefficient is correctly performed, and it can be predicted that the absolute value of the Seebeck coefficient of the present thermoelectric conversion material increases.

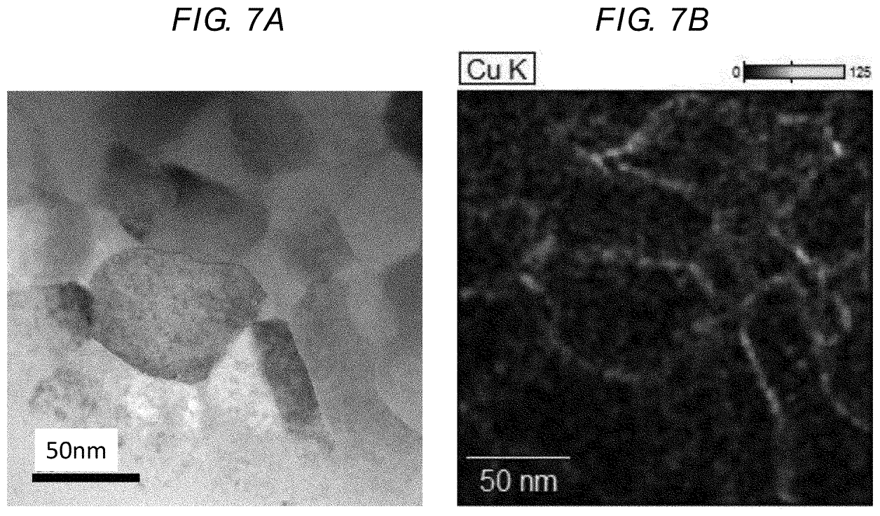

Referring to FIGS. 7A and 7B, Cu, which is an element of the metal alloy N, existing on a constituent element grain boundary in the Fe₂TiVSi-based thermoelectric conversion material of the present embodiment will be described by comparing a STEM image (FIG. 7A) and STEM-EDX mapping (FIG. 7B). In FIG. 7B, a contrast of a region where Cu exists is brightly (white) displayed. Scales 0 to 125 on the upper right portion are an index (arbitrary unit) of contrast. FIGS. 7A and 7B illustrate results of observing the same region of the thermoelectric conversion material, but it can be seen that the Cu element forms a layer structure and exists on the boundary surface position of the crystal grain. From this, a low electrical resistivity and a low thermal conductivity are expected to be compatible with each other due to the presence of the above-described grain boundary layer.

In the Fe₂TiVSi-based thermoelectric conversion material of the present embodiment, Cu is segregated on the boundary surface of the crystal grain. The state of the segregation can be verified by comparing concentrations of Cu in the crystal grain and on the grain boundary phase, based on composition analysis by the STEM-EDX as described above, and segregating a specific element on the grain boundary phase rather than in the crystal grain. For example, if any two points in the crystal grain and on the grain boundary phase are measured by the STEM-EDX, and concentrations are different from each other by two times or more, significant uneven distribution of the element can be identified. However, since local unevenness may be considered, a region of a several nm, for example, 5 nm square, is cut from the inside of the crystal grain, an average thereof is measured, a region of a several nm, for example, 5 nm square, is similarly cut from the inside of the grain boundary phase, an average thereof is measured, and more objective evaluation can be performed by comparing the averages.

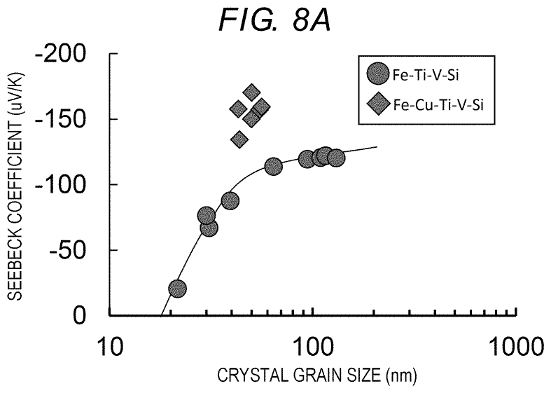

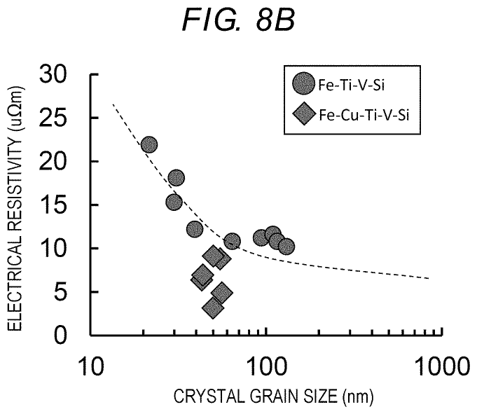

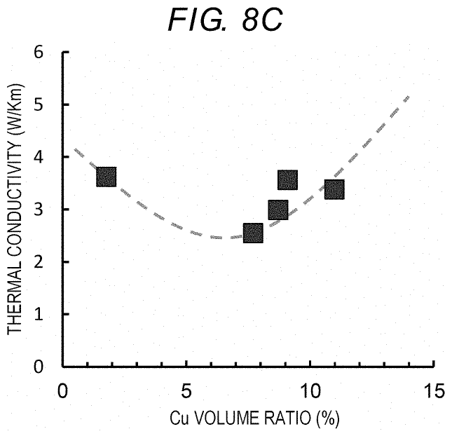

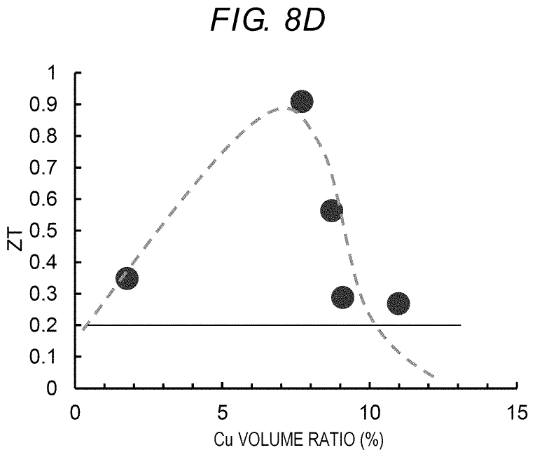

FIGS. 8A to 8D illustrate results of measuring thermoelectric conversion characteristics of the Fe₂TiVSi-based thermoelectric conversion material of the present embodiment.

FIG. 8A illustrates a result of comparing a characteristic (rectangular plots) of a Fe₂TiVSi-based thermoelectric conversion material to which Cu is added as the metal alloy N of the present embodiment, and a characteristic (circular plots) of a Fe₂TiVSi-based thermoelectric conversion material to which Cu is not added. A production process condition other than the composition is the same. The horizontal axis indicates a crystal grain size, and the vertical axis indicates a Seebeck coefficient. Herein, the crystal grain size is calculated from a full width at half maximum of a main peak of a main phase in an XRD profile observed by XRD, and a Scherrer's formula. It can be seen from FIG. 8A that the present thermoelectric conversion material having the crystal grain size of 100 nm or less to have the above-described electron structure has a high Seebeck coefficient of 120 μV/K<|S|<170 μV/K.

FIG. 8B illustrates a result of comparing a characteristic (rectangular plots) of the Fe₂TiVSi-based thermoelectric conversion material to which Cu is added as the metal alloy N of the present embodiment, and a characteristic (circular plots) of the Fe₂TiVSi-based thermoelectric conversion material to which Cu is not added. A production process condition other than the composition is the same. The horizontal axis indicates a crystal grain size, and the vertical axis indicates an electrical resistivity. It can be seen from FIG. 8B that the electrical resistivity tends to increase according to reduction of the crystal grain size, but the thermoelectric conversion material has the low electrical resistivity of from 5 μΩm to 10 μΩm, due to the presence of the metal alloy N.

FIG. 8C illustrates a relationship between a volume ratio of the metal alloy N and a thermal conductivity in the Fe₂TiVSi-based thermoelectric conversion material to which Cu is added as the metal alloy N of the present embodiment. The volume ratio of the metal alloy N is calculated from a ratio between an integrated intensity of the main peak of the main phase and an integrated intensity of the main peak of the metal alloy N in the XRD profile which is obtained by XRD-measuring the Fe₂TiVSi-based thermoelectric conversion material to which Cu is added. As illustrated in the drawing, it can be seen that the thermal conductivity is reduced according to an increase of the volume ratio of Cu which is the metal alloy N, and then increases. It can be seen from the drawing that a low thermal conductivity is obtained at the volume ratio of Cu of 2% to 10%. In addition, a lower thermal conductivity can be obtained at the volume ratio of Cu of 3% to 9%.

FIG. 8D is a graph illustrating a relationship between the volume ratio of the metal alloy N and a performance index ZT, based on all of the thermoelectric conversion characteristics illustrated in FIGS. 8A to 8C. As illustrated in FIG. 8D, it can be seen that the thermoelectric conversion material of the present embodiment has a maximum value of ZT of 0.91 at the volume ratio of the metal alloy N of about 7%. It can be seen that an excellent ZT is obtained at the volume ratio of Cu of 2% to 10%, compared with a case where a ZT of a Fe₂VAl-based full Heusler alloy which is a related-art material is 0.2. In addition, a higher ZT is obtained at the volume ratio of Cu of 3% to 9%, and a still higher ZT is obtained at the volume ratio of 4% to 9%. As a result of X-ray spectroscopic analysis, it can be seen that the peak of the main phase component is not changed even if the volume ratio of Cu is changed.

### Second Embodiment

An effect achieved when a heavy element such as La, Bi, Nb, etc. is added to the Cu-based alloy as the metal alloy N will be described.

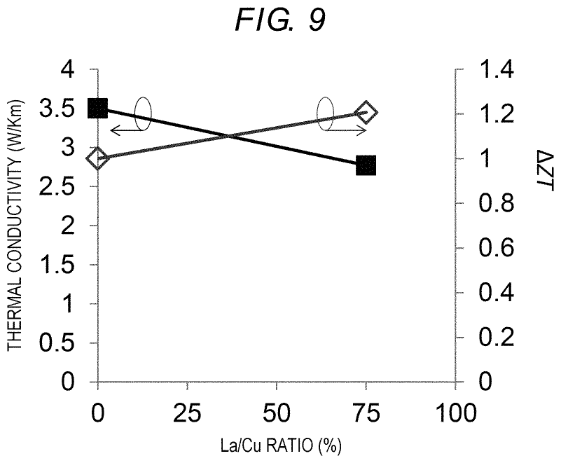

FIG. 9 illustrates an effect obtained by adding La. The horizontal axis indicates a weight ratio of Cu and La included as the metal alloy N. It can be seen that when La is added to Cu which is the metal alloy N by 75%, the thermal conductivity is reduced due to the effect of La which is a heavy element as illustrated in FIG. 9, and as a result, the ZT increases. The vertical axis on the right indicates an improvement effect ΔZT of the ZT when the ZT is set to 1 without adding La.

A preferred effect can be achieved even if an Ag—La alloy or an Au—La alloy which is similar to the Cu-based alloy is used as the metal alloy N.

It can be seen that, if a content of V, which is an amount of substituted V in the above-described Fe₂TiSi-based full Heusler alloy, is 1.0 to 4.2 at %, the ZT thereof is at a high level.

Although the invention achieved by the present inventors has been described specifically based on the embodiments thereof, the present invention is not limited to the above-described embodiments, and various changes can be made without departing from the scope of the present invention.

The present invention is applied to the thermoelectric conversion material and is effective.

What is claimed is:

1. A thermoelectric conversion material, comprising:
a main phase; and
a grain boundary phase, wherein
the main phase is a Fe₂TiSi-based full Heusler alloy,
the grain boundary phase includes a metal N slightly solid-soluble in Fe₂TiSi, and
a volume ratio of the grain boundary phase is 2% to 10%.

2. The thermoelectric conversion material according to claim 1, wherein the metal N is an alloy including at least one element selected from Cu, Ag, Au, La, Bi, and Nb.

3. The thermoelectric conversion material according to claim 1, wherein a thickness of the grain boundary phase is 1 to 10 nm at least in part.

4. The thermoelectric conversion material according to claims 1, wherein the volume ratio of the grain boundary phase is 3% to 9%.

5. The thermoelectric conversion material according to claims 1, wherein the volume ratio of the grain boundary phase is 4% to 9%.

6. The thermoelectric conversion material according to claims 1, wherein
the Fe₂TiSi-based full Heusler alloy includes Fe, Ti, V, Si, and Al,
Ti is contained more than V, and
Si is contained more than Al.

7. The thermoelectric conversion material according to claims 1, wherein, in the Fe₂TiSi-based full Heusler alloy, a content of Fe exceeds 25 at %, a content of Ti exceeds 12.5 at %, and a content of Si exceeds 12.5 at %.

8. The thermoelectric conversion material according to claims 1, wherein, in the Fe₂TiSi-based full Heusler alloy, at least one element selected from carbon (C) , oxygen (O), and nitrogen (N) is solid-soluted, and a content thereof is 1000 ppm or less.

9. A thermoelectric conversion module comprising:
a thermoelectric conversion unit; and
a first electrode and a second electrode which electrically and thermally contact the thermoelectric conversion unit, wherein
at least a part of the thermoelectric conversion unit is formed of a thermoelectric conversion material,
the thermoelectric conversion material includes a main phase and a grain boundary phase,
the main phase is a Fe₂TiSi-based full Heusler alloy,
the grain boundary phase includes a metal N slightly solid-soluble in Fe₂TiSi, and
a volume ratio of the grain boundary phase is 2% to 10%.

10. A production method of a thermoelectric conversion material, the method comprising:
a preparation process of preparing raw material powder of an amorphized Fe₂TiSi-based full Heusler alloy, and raw material powder including a metal N;
a heating process of heating the raw material powder; and
a cooling process of cooling a product material after the heating process, wherein
a grain boundary phase is formed between main phases of a thermoelectric conversion material formed of the Fe₂TiSi-based full Heusler alloy, by precipitating the metal N, and a volume ratio of the grain boundary phase is 2% to 10%.

11. The production method of a thermoelectric conversion material according to claim 10, wherein, in the heating process, a heating temperature of the raw material powder is set to 550° C. to 700° C., and a heating time is set to from 3 minutes to 10 hours inclusive.

12. The production method of a thermoelectric conversion material according to claim 10, wherein, in the heating process, the raw material powder is sintered under pressure of 40 MPa to 5 GPa, and when the sintering is performed, the temperature increases to a target temperature of a range of 550° C. to 700° C., and then the powder is maintained at the target temperature for 3 to 180 minutes.
